(19) United States
(12) Patent Application Publication
(10) Pub. No.: US 2012/0282780 A9
(43) Pub. Date: Nov. 8, 2012

(54) ETCH WITH HIGH ETCH RATE RESIST MASK

(75) Inventors: Andrew R. Romano, Pleasanton, CA (US); S. M. Reza Sadjadi, Saratoga, CA (US)

(73) Assignee: LAM RESEARCH CORPORATION, Fremont, CA (US)

(21) Appl. No.: 12/339,511

(22) Filed: Dec. 19, 2008

Related U.S. Application Data
(63) Continuation-in-part of application No. 11/223,363, filed on Sep. 9, 2005, now Pat. No. 7,491,647.
Application No. 11/223,363 is a continuation-in-part of application No. 11/076,087, filed on Mar. 8, 2005, now Pat. No. 7,241,683.
(60) Provisional application No. 61/016,366, filed on Dec. 21, 2007.

(51) Int. Cl. H01L 21/3065; C23F 1/08

(52) U.S. Cl. 438/736; 156/345.26; 257/E21.218

(57) ABSTRACT

A method for etching features into an etch layer is provided. A patterned mask is formed over the etch layer, wherein the patterned mask is of a high etch rate photoresist material, wherein the patterned mask has patterned mask features. A protective layer is deposited on the patterned mask of high etch rate photoresist material by performing a cyclical deposition, wherein each cycle, comprises a depositing phase for depositing a deposition layer over the exposed surfaces, including sidewalls of the patterned mask of high etch rate photoresist material and a profile shaping phase for providing vertical sidewalls. Features are etched into the etch layer using the protective layer as a mask. The protective layer is removed.

### CROSS REFERENCE TO RELATED APPLICATIONS

This application claims priority under 35 U.S.C. §119(e) from pending U.S. Provisional Application No. 61/016,366, entitled “ETCH WITH HIGH ETCH RATE RESIST MASK,” filed Dec. 21, 2007, which is incorporated by reference in its entirety for all purposes.

### BACKGROUND OF THE INVENTION

The present invention relates to the formation of semiconductor devices.

During semiconductor wafer processing, features of the semiconductor device are defined in the wafer using well-known patterning and etching processes. In these processes, a photoresist (PR) material is deposited on the wafer and then is exposed to light filtered by a reticle. The reticle is generally a glass plate that is patterned with exemplary feature geometries that block light from propagating through the reticle.

After passing through the reticle, the light contacts the surface of the photoresist material. The light changes the chemical composition of the photoresist material such that a developer can remove a portion of the photoresist material. In the case of positive photoresist materials, the exposed regions are removed, and in the case of negative photoresist materials, the unexposed regions are removed. Thereafter, the wafer is etched to remove the underlying material from the areas that are no longer protected by the photoresist material, and thereby define the desired features in the wafer. Photoresist material requires an etch resistant component to prevent the photoresist mask from being removed too quickly during the etch process, i.e. to function as an etch mask. Etch resistance additives are discussed in U.S. Pat. No. 6,103,445 by Willson et al., which was issued Aug. 15, 2000 and in U.S. Pat. No. 6,143,466 by Choi, which was issued Nov. 7, 2000, where both patents are incorporated by reference for all purposes. An example of etch resistance additives are noroborenes, adamantanes and their derivatives for 193 resist and benzenes and phenyls and their derivatives for 248 resist.

These patents also disclose that chemically amplified photoresist material may also have a chemical amplification components to provide a chemically amplified photoresist composition.

### SUMMARY OF THE INVENTION

To achieve the foregoing and in accordance with the purpose of the present invention a method for etching features into an etch layer is provided. A patterned mask is formed over the etch layer, wherein the patterned mask is of a photoresist material with little or no etch resistance, wherein the patterned mask has patterned mask features. A protective layer is deposited on the patterned mask of this high etch rate photoresist material by performing a cyclical deposition, wherein each cycle, comprises a depositing phase for depositing a deposition layer over the exposed surfaces, including sidewalls of the patterned mask of this high etch rate photoresist material and a profile shaping phase for providing vertical sidewalls. Features are etched into the etch layer using the protective layer as a mask. The protective layer is removed.

In another manifestation of the invention an apparatus for forming features in an etch layer, wherein the layer is supported by a substrate and wherein the etch layer is covered by a patterned high etch rate photoresist mask with mask features, wherein the high etch rate photoresist is free of etch resistance additives or with etch enhancing additives is provided. A plasma processing chamber is provided comprising a chamber wall forming a plasma processing chamber enclosure, a substrate support for supporting a substrate within the plasma processing chamber enclosure, a pressure regulator for regulating the pressure in the plasma processing chamber enclosure, at least one electrode for providing power to the plasma processing chamber enclosure for sustaining a plasma, a gas inlet for providing gas into the plasma processing chamber enclosure, and a gas outlet for exhausting gas from the plasma processing chamber enclosure. A gas source is in fluid connection with the gas inlet, and comprises a deposition gas source, a profile shaping gas source, and an etch gas source. A controller is controllably connected to the gas source and the at least one electrode and comprises at least one processor and computer readable media. The computer readable media comprises computer readable code for providing for two to three cycles a protective layer deposition that forms a protective layer with sidewalls with a thickness between 0.5 nm and 30 nm wherein each cycle comprises computer readable code for providing a flow of a deposition gas from the deposition gas source to the plasma processing chamber enclosure, computer readable code for forming the deposition gas into a plasma, computer readable code for stopping the flow of the deposition gas to the plasma processing chamber enclosure, computer readable code for providing a flow of a profile shaping gas from the profile shaping gas source to the plasma processing chamber enclosure after the flow of the first deposition gas is stopped, computer readable code for forming the profile shaping gas into a plasma, and computer readable code for stopping the flow of the profile shaping gas to the plasma processing chamber enclosure, computer readable code for providing a flow of an etchant gas from the etchant gas source to the plasma processing chamber, computer readable code for etching features in the etch layer, using the etchant gas, and computer readable code for stripping the protective layer and the high etch rate photoresist mask.

In another manifestation of the invention a method for etching features into an etch layer is provided. A patterned mask is formed over the etch layer, wherein the patterned mask is of a high etch rate photoresist material, wherein the patterned mask has patterned mask features. A protective layer is deposited on the patterned mask of the high etch rate photoresist material by performing a cyclical deposition, wherein each cycle, comprises a depositing phase for depositing a deposition layer over the exposed surfaces, including sidewalls of the patterned mask of high etch rate photoresist material and a profile shaping phase for providing vertical sidewalls. The high etch rate photoresist material is removed, leaving sidewalls of the protective layer. Features are etched into the etch layer using the sidewalls of the protective layer as a mask. The protective layer is removed.

Another manifestation of the invention provides an apparatus for forming features in an etch layer, wherein the layer is supported by a substrate and wherein the etch layer is covered by a patterned high etch rate photoresist mask with mask features, wherein the high etch rate photoresist is free of etch resistance additives. A plasma processing chamber is provided, comprising a chamber wall forming a plasma processing chamber enclosure, a substrate support for supporting a substrate within the plasma processing chamber enclosure, a pressure regulator for regulating the pressure in the plasma processing chamber enclosure, at least one electrode for providing power to the plasma processing chamber enclosure for sustaining a plasma, a gas inlet for providing gas into the plasma processing chamber enclosure, and a gas outlet for exhausting gas from the plasma processing chamber enclosure. A gas source is in fluid connection with the gas inlet and comprises a deposition gas source, a profile shaping gas source, and an etch gas source. A controller is controllably connected to the gas source and the at least one electrode, and comprises at least one processor and computer readable media. The computer readable media comprises computer readable code for providing a plurality of cycles for forming a protective layer with sidewalls, where the protective layer is not formed on top surfaces of the high etch rate photoresist wherein each cycle, comprising computer readable code for providing a flow of a deposition gas from the deposition gas source to the plasma processing chamber enclosure, computer readable code for forming the deposition gas into a plasma, computer readable code for stopping the flow of the deposition gas to the plasma processing chamber enclosure, computer readable code for providing a flow of a profile shaping gas from the profile shaping gas source to the plasma processing chamber enclosure after the flow of the first deposition gas is stopped; computer readable code for forming the profile shaping gas into a plasma, and computer readable code for stopping the flow of the profile shaping gas to the plasma processing chamber enclosure, computer readable code for removing the high etch rate photoresist without removing the sidewalls of the protective layer, computer readable code for providing a flow of an etchant gas from the etchant gas source to the plasma processing chamber, computer readable code for etching features in the etch layer, using the etchant gas and using the protective layer sidewalls as a mask, and computer readable code for stripping the protective layer and the high etc rate photoresist mask.

In another manifestation of the invention a method for etching features into an etch layer is provided. A patterned mask is formed over the etch layer, wherein the patterned mask is of a high etch rate photoresist material, wherein the patterned mask has patterned mask features. A protective layer is deposited on the patterned mask of high etch rate photoresist material by performing a cyclical deposition, wherein each cycle, comprises a depositing phase for depositing a deposition layer over the exposed surfaces, including sidewalls of the patterned mask of high etch rate photoresist material and a profile shaping phase for providing vertical sidewalls, wherein the protective layer is deposited over the top and sidewalls of the high etch rate photoresist mask. Features are etched into the etch layer using the protective layer as a mask. The protective layer is removed.

These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 is a high level flow chart of a process that may be used in an embodiment of the invention.

FIGS. 2A-D are schematic cross-sectional views of a stack processed according to an embodiment of the invention.

FIG. 3 is a high level flow chart of another process that may be used in an embodiment of the invention.

FIGS. 4A-E are schematic cross-sectional views of another stack processed according to an example of the invention.

FIG. 5 is a schematic view of a plasma processing chamber that may be used in practicing the invention.

FIGS. 6A-B illustrate a computer system, which is suitable for implementing a controller used in embodiments of the present invention.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Using an etch resistance additive may cause various problems. Etch resistance additives increase the cost of a photoresist. Etch resistance additives may reduce transparency of the photoresist to various frequencies of light. Etch resistance additives may increase line edge roughening. Since different etch resistance additives may be effective for only some of the different exposure frequencies, etch resistance additives require increased complexity for the lithographic process and in the manufacture and development of photoresist systems.

When the wafer is heated after exposure, a catalysis occurs, which amplifies the reaction of a single photon around where the photon is absorbed, so that a single photon may be amplified to cause 100 or more reactions. Such an amplification may cause a blur of resolution that may be on the order of 15 nm. For EUV lithography and high NA 193 nm immersion a 30 nm resolution is desirable. The blur from chemical amplification may prevent such a resolution.

Since etch resistance additives make the photoresist more resistant to etch, chemical amplification is more desirable with the presence of etch resistance additives. With a high etch rate photoresist that is free of etch resistance additives, in some embodiments such photoresists may also be free of chemical amplification additives (non-chemically amplified).

Photoresist by its nature “resists” etch but etch resistance additives increase the cost of development and the raw material cost of those polymers. Etch resistance additives also complicate the making of negative resists as cross-linking of bulky monomers encumber polymer chains and will be more difficult to form cross-linking and therefore decreases the contrast of such a system. Typically it is thought that there is a correlation between line edge roughness and monomer size. Monomer units are larger when large etch groups must be attached to the side chain or incorporated in the polymer backbone. In addition etch resistance additives complicate the creation of highly sensitive non-chemically amplified resists (for example for use in EUV or high NA immersion) where diffusion is an issue. The making of highly sensitive low LER non-chemically amplified can be greatly simplified by leaving out etch resistance additives and using an embodiment of the invention.

The invention uses a high etch rate photoresist that has a low etch resistance in etching an etch layer. More preferably, the invention uses a high etch rate photoresist that is free of etch resistant additives as a patterned mask for etching an etch layer.

An embodiment of the invention may use a high etch rate resist mentioned between two deposited polymers with higher selectivity to form what is called a Self Aligned Double Patterned Process. These SaDPT processes can be used to double the patterning density required to decrease the pitch size of the imaging tool when the wavelength of the exposure cannot achieve a smaller pitch.

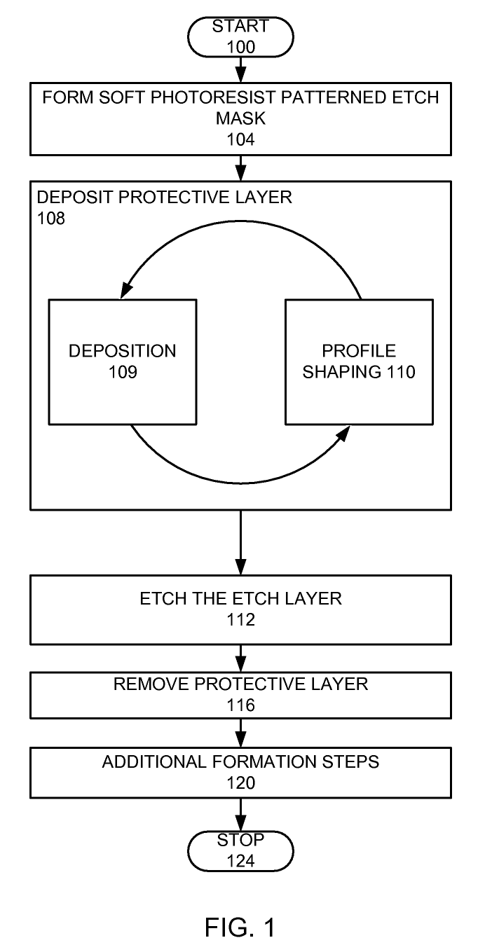

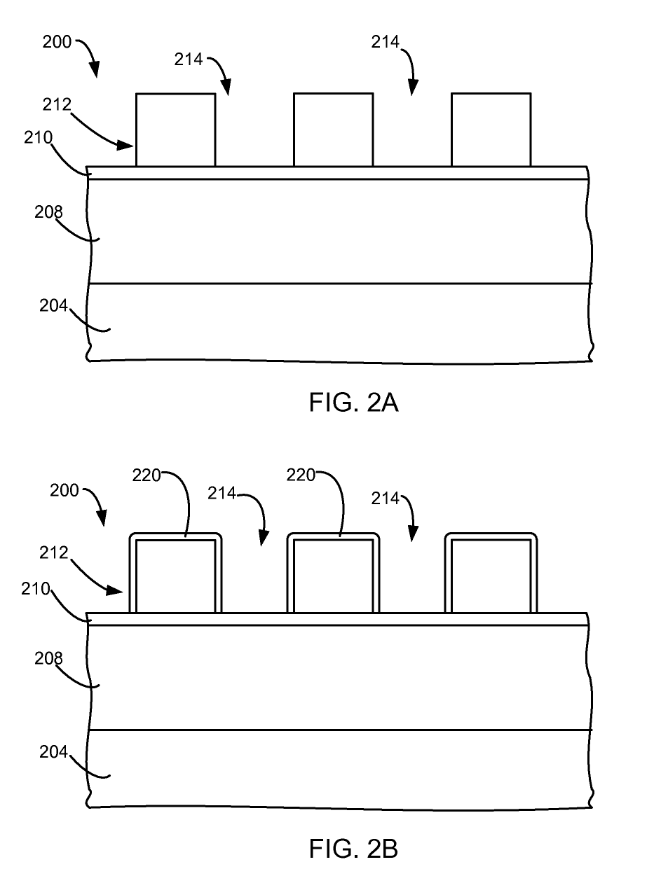

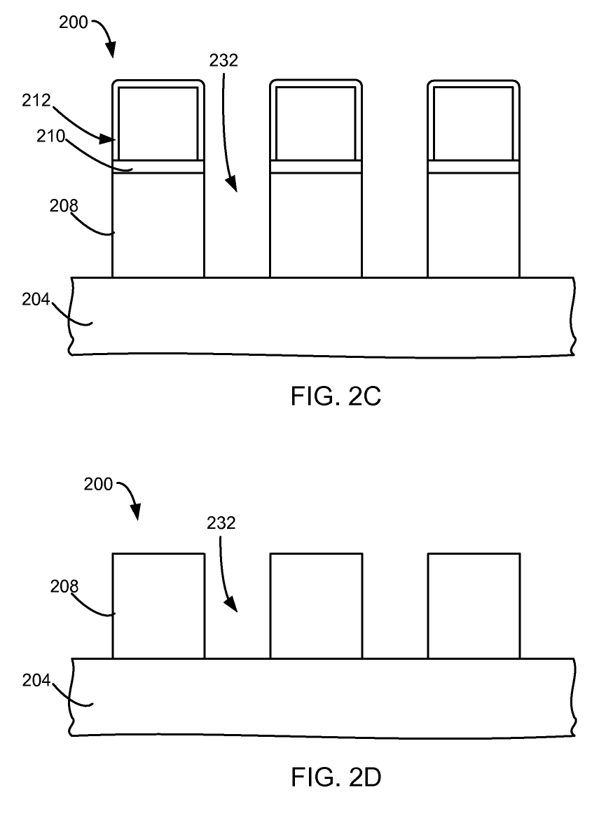

To facilitate understanding, FIG. 1 is a high level flow chart of a process that may be used in an embodiment of the invention. A high etch rate photoresist patterned etch mask is formed over an etch layer (step 104). A high etch rate photoresist has a low etch resistance. More preferably, a high etch rate photoresist is free of etch resistance additives. FIG. 2A is a schematic cross-sectional view of an etch layer 208 over a substrate 204. A patterned etch mask of a high etch rate photoresist material 212 with mask features 214 is over an antireflective layer (ARL) 210, over the etch layer 208, over a substrate 204, which forms a stack 200.

A cyclical formation of a protective layer is performed to form a protective layer on the high etch rate photoresist (step 108). The cyclical protective layer formation process comprises at least two steps of depositing a layer over the sidewalls of the etch mask features 214 (step 109) and then shaping the profile of the deposition layer (step 110). FIG. 2B is a schematic cross-sectional view of the patterned etch mask 212 with a protective layer 220, formed by the cyclical protective layer formation, deposited over the sidewalls of the feature 214. In this embodiment, the formation of the protective layer does not form a layer over horizontal ARL 210 surface at the bottom of the mask features 214, as shown. In this example, the protective layer is formed on the horizontal surface on top of the photoresist mask.

Features are then etched into the etch layer to 208 (step 112). FIG. 2C shows a feature 232 etched into the etch layer 208. The protective layer may then be removed (step 116). This step may simultaneously remove the patterned mask of high etch rate photoresist and the ARL. In another embodiment, these layers may be removed in individual steps. FIG. 2D shows the stack 200 after the deposition layer and etch mask have been removed. Additional formation steps may be performed (step 120). For example, a contact may then be formed in the feature. To provide a dual damascene structure, a trench may be etched before the contact is formed. In the alternative, the additional steps may be used to form memory devices.

Example of Dielectric Etch

In an example of the invention, a layer to be etched is a dielectric layer 208, which is placed over a substrate 204, as shown in FIG. 2A. An antireflective layer (ARL) 210 is placed over the dielectric layer 208. A patterned high etch rate photoresist mask 212 of 248 nm photoresist is placed over the ARL 210 (step 104). Photoresist mask features 214 are formed in the patterned high etch rate photoresist mask 212. Presently, for 248 nm photoresist etch mask a typical CD for the photoresist may be 100-250 nm, using conventional processes. The substrate is placed in a plasma processing chamber.

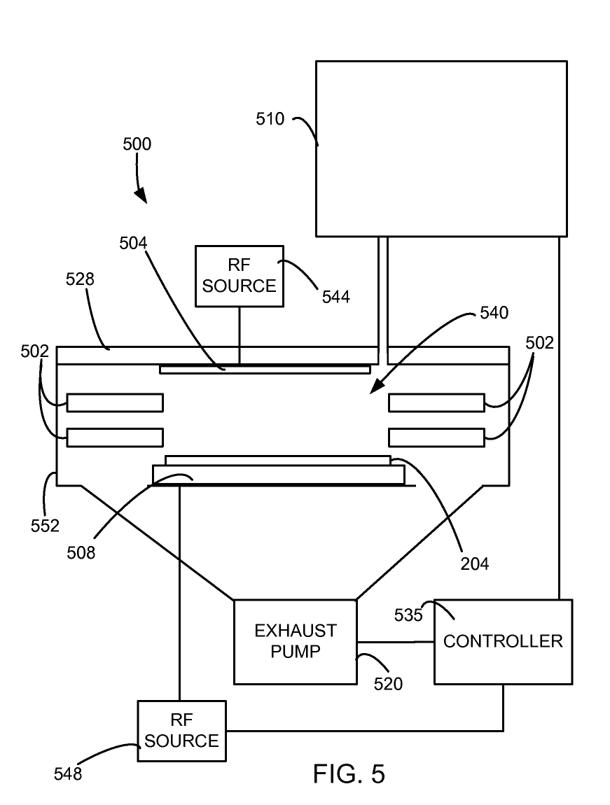

FIG. 5 is a schematic view of a plasma processing chamber 500 that may be used for performing the protective layer formation, etching, and stripping. The plasma processing chamber 500 comprises confinement rings 502, an upper electrode 504, a lower electrode 508, a gas source 510, and an exhaust pump 520. Within plasma processing chamber 500, the substrate 204 is positioned upon the lower electrode 508. The lower electrode 508 incorporates a suitable substrate chucking mechanism (e.g., electrostatic, mechanical clamping, or the like) for holding the substrate 204. The reactor top 528 incorporates the upper electrode 504 disposed immediately opposite the lower electrode 508. The upper electrode 504, lower electrode 508, and confinement rings 502 define the confined plasma volume. Gas is supplied to the confined plasma volume by the gas source 510 and is exhausted from the confined plasma volume through the confinement rings 502 and an exhaust port by the exhaust pump 520. A first RF source 544 is electrically connected to the upper electrode 504. A second RF source 548 is electrically connected to the lower electrode 508. Chamber walls 552 surround the confinement rings 502, the upper electrode 504, and the lower electrode 508. Both the first RF source 544 and the second RF source 548 may comprise a 27 MHz power source and a 2 MHz power source. Different combinations of connecting RF power to the electrode are possible. In the case of Exelan HPT™, which is basically the same as an Exelan HP with a Turbo Pump attached to the chamber, made by LAM Research Corporation™ of Fremont, Calif., which may be used in a preferred embodiment of the invention, both the 27 MHz and 2 MHz power sources make up the second RF power source 548 connected to the lower electrode, and the upper electrode is grounded. A controller 535 is controllably connected to the RF sources 544, 548, exhaust pump 520, and the gas source 510. The Exelan HPT would be used when the layer to be etched 208 is a dielectric layer, such as silicon oxide or organo silicate glass.

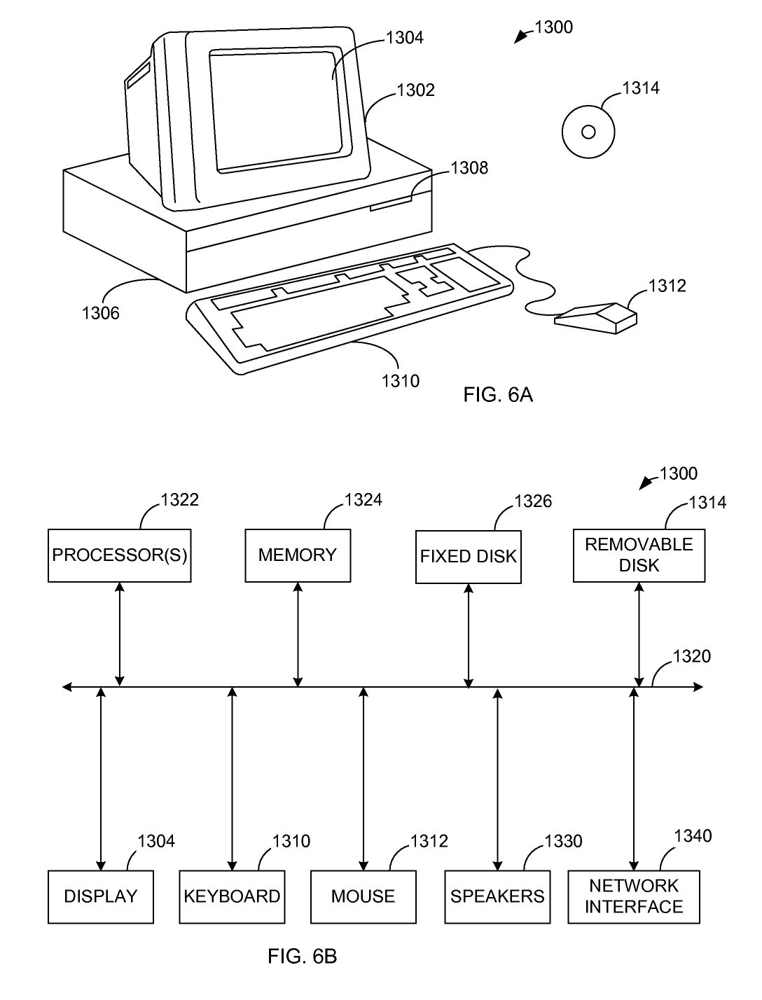

FIGS. 6A and 6B illustrate a computer system 1300, which is suitable for implementing a controller 535 used in embodiments of the present invention. FIG. 6A shows one possible physical form of the computer system. Of course, the computer system may have many physical forms ranging from an integrated circuit, a printed circuit board, and a small handheld device up to a huge super computer. Computer system 1300 includes a monitor 1302, a display 1304, a housing 1306, a disk drive 1308, a keyboard 1310, and a mouse 1312. Disk 1314 is a computer-readable medium used to transfer data to and from computer system 1300.

FIG. 6B is an example of a block diagram for computer system 1300. Attached to system bus 1320 is a wide variety of subsystems. Processor(s) 1322 (also referred to as central processing units, or CPUs) are coupled to storage devices, including memory 1324. Memory 1324 includes random access memory (RAM) and read-only memory (ROM). As is well known in the art, ROM acts to transfer data and instructions uni-directionally to the CPU and RAM is used typically to transfer data and instructions in a bi-directional manner. Both of these types of memories may include any suitable of the computer-readable media described below. A fixed disk 1326 is also coupled bi-directionally to CPU 1322; it provides additional data storage capacity and may also include any of the computer-readable media described below. Fixed disk 1326 may be used to store programs, data, and the like and is typically a secondary storage medium (such as a hard disk) that is slower than primary storage. It will be appreciated that the information retained within fixed disk 1326 may, in appropriate cases, be incorporated in standard fashion as virtual memory in memory 1324. Removable disk 1314 may take the form of any of the computer-readable media described below.

CPU 1322 is also coupled to a variety of input/output devices, such as display 1304, keyboard 1310, mouse 1312 and speakers 1330. In general, an input/output device may be any of: video displays, track balls, mice, keyboards, microphones, touch-sensitive displays, transducer card readers, magnetic or paper tape readers, tablets, styluses, voice or handwriting recognizers, biometrics readers, or other computers. CPU 1322 optionally may be coupled to another computer or telecommunications network using network interface 1340. With such a network interface, it is contemplated that the CPU might receive information from the network, or might output information to the network in the course of performing the above-described method steps. Furthermore, method embodiments of the present invention may execute solely upon CPU 1322 or may execute over a network such as the Internet in conjunction with a remote CPU that shares a portion of the processing.

In addition, embodiments of the present invention further relate to computer storage products with a computer-readable medium that have computer code thereon for performing various computer-implemented operations. The media and computer code may be those specially designed and constructed for the purposes of the present invention, or they may be of the kind well known and available to those having skill in the computer software arts. Examples of computer-readable media include, but are not limited to: magnetic media such as hard disks, floppy disks, and magnetic tape; optical media such as CD-ROMs and holographic devices; magneto-optical media such as floptical disks; and hardware devices that are specially configured to store and execute program code, such as application-specific integrated circuits (ASICs), programmable logic devices (PLDs) and ROM and RAM devices. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

Other examples may use other devices to carry out the invention.

Next, the cyclical formation of the protective layer is performed to provide the protective layer (step 108). In this example, the deposition phase (step 109) comprises providing a deposition gas and generating a plasma from the deposition gas to form a deposition layer. In this example, the deposition gas comprises a polymer forming recipe. An example of such a polymer forming recipe is a hydrocarbon gas such as, C₂H₂, CH₄ and C₂H₄, and a fluorocarbon gas, such as CH₃F, CH₂F₂, CHF₃, C₄F₆, and C₄F₈. Another example of a polymer forming recipe would be a fluorocarbon chemistry and a hydrogen containing gas, such as a recipe of CF₄ and H₂. The deposition gas is then stopped.

The profile shaping (step 110) comprises providing a profile shaping gas and generating a profile shaping plasma from the profile shaping gas to shape the profile of the deposition layer 420. The profile shaping gas is different from the deposition gas. As illustrated, the deposition phase (step 109) and the profile shaping phase (step 110) occur at different times. In this example the profile shaping gas comprises a fluorocarbon chemistry, such as CF₄, CHF₃, and CH₂F₂. Other gases such as COS, O₂, N₂, and H₂ may be used. In this example, power is supplied at 0 watts at 2 MHz and 800 watts at 27 MHz. The profile shaping gas is then stopped.

In this example, the deposition phase (step 109) is repeated a second time. The same deposition recipe is used here as described above. In alternative embodiments, the deposition recipe can also be modified from the recipe in the first deposition phase.

The profile shaping phase (step 110) is repeated a second time. The same profile shaping recipe is used here as described above. The profile shaping recipe can also be modified from the recipe in the first deposition phase.

The protective layer formation process (step 108) can repeat for a number of cycles as until the desired protective layer is formed. Preferably, in this example, the number of cycles may be from 1 to 10 times. More preferably, the number of cycles is 2 to 3 times. Preferably, sidewalls of the protective layer are 0.5 nm to 30 nm thick. More preferably, sidewalls of the protective layer are 0.5 to 10 nm.

After the formation of the protective layer (step 108) is completed, the dielectric layer is then etched using the protective layer (step 112). The etch comprises providing an etch gas and forming an etch plasma from the etch gas. In this example a different etch recipe is used for the dielectric layer etch (step 112) than the profile shaping recipe used in the profile shaping phase (step 110) or the recipe in the deposition phase (step 109). This is because it is desirable that the dielectric layer 208 is not etched during the protective layer formation (step 108). An example of an etch chemistry for etching the dielectric layer would be C₄F₆ with O₂ or N₂.

The protective layer is then removed (step 116). In this example a standard photoresist strip is used to remove the protective layer mask. Additional formation steps may also be performed (step 120).

Preferably, each deposition layer for each deposition phase is between 0.5 nm to 30 nm thick. More preferably, each deposition layer for each deposition phase is between 0.5 nm to 5 nm thick. Most preferably, each deposition layer for each deposition phase is between 1 to 5 nm thick.

In different embodiments of the inventions, the etch layer may be a dielectric layer, such as a low-k dielectric layer or a metal containing layer. The etch layer may also be a hardmask layer, such as amorphous carbon or a SiN layer that serves as a hardmask for the later etching of a feature.

Reduced Pitch Length Process

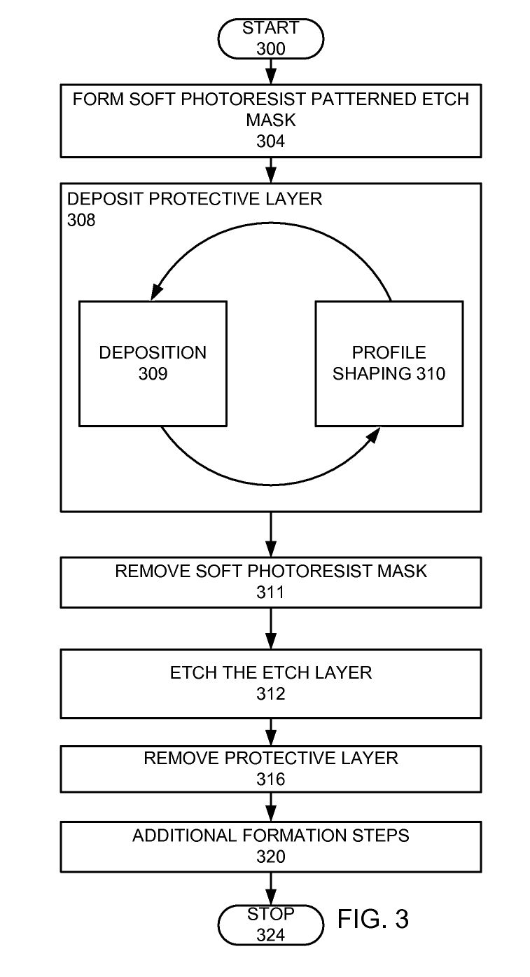

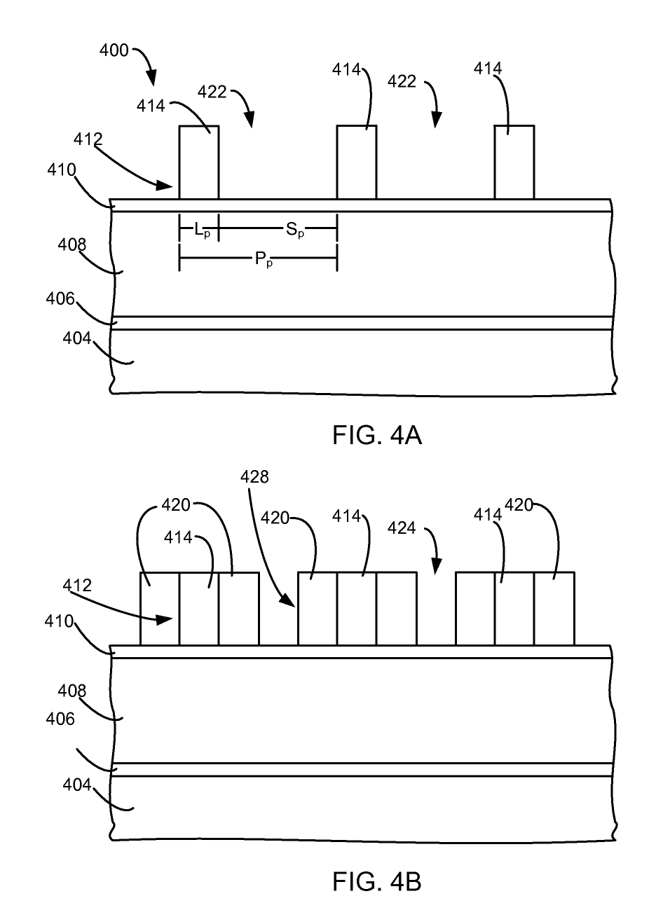

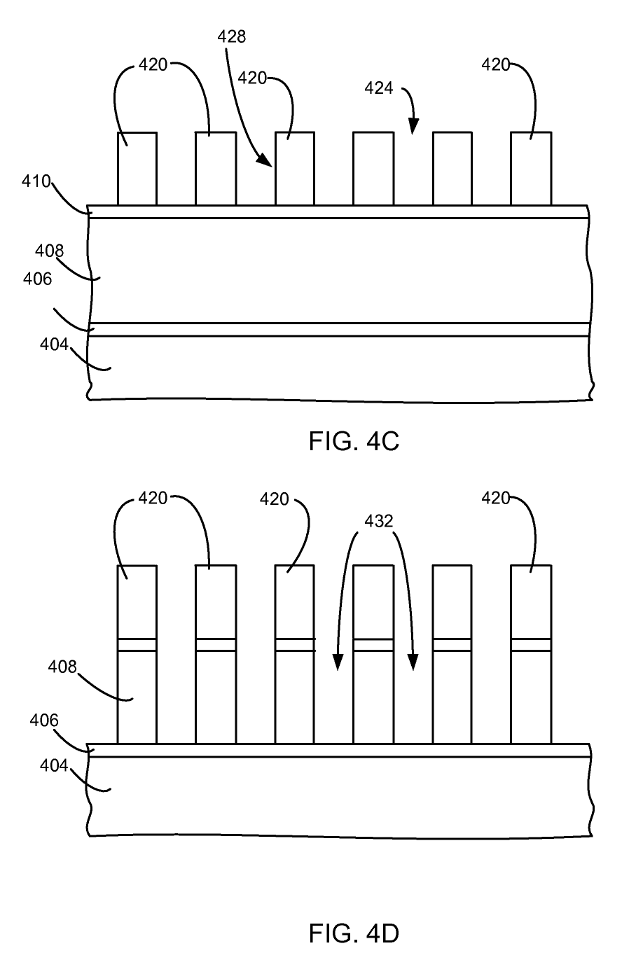

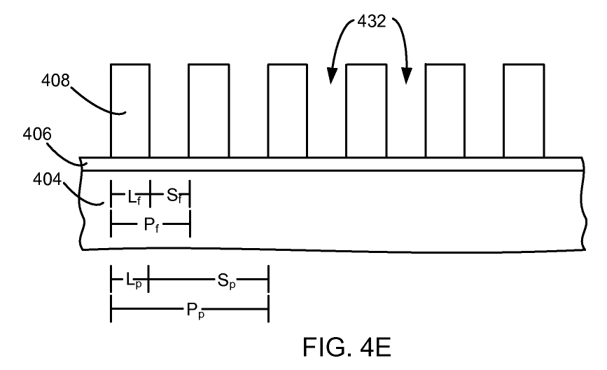

In another example of the invention, feature pitch may be increased. FIG. 3 is a high level flow chart of a process that may be used in an embodiment of the invention. A high etch rate photoresist patterned etch mask is formed over an etch layer (step 304). A high etch rate photoresist has a low etch resistance. More preferably, a high etch rate photoresist is free of etch resistance additives. FIG. 4A is a cross-sectional view of a patterned mask in an embodiment of the invention. Over a substrate 404, such as a wafer a barrier layer 406 may be placed. Over the barrier layer 406 an etch layer 408 such as a conductive metal layer or a polysilicon layer or a dielectric layer is formed. Over the etch layer 408 an antireflective layer (ARL) 410 such as a DARC layer is formed. A patterned first mask of a high etch rate photoresist 412 is formed over the ARL 410. In this example the etch mask features 414 of the line mask have a width defined as the line width “Lₚ”, as shown. The spaces 422 in the high etch rate photoresist mask have a width “Sₚ”, as shown. The pitch length “Pₚ” of the high etch rate photoresist mask is defined as the sum of the line width and the space width Pₚ=Lₚ+Sₚ, as shown. These widths are determined by the resolution of the lithographic techniques used to form the high etch rate photoresist mask. It is desirable to reduce the pitch length.

A cyclical formation of a protective layer is performed to form a protective layer on the high etch rate photoresist (step 308). The cyclical protective layer formation process comprises at least two steps of depositing a layer over the sidewalls of the etch mask features 414 (step 309) and then shaping the profile of the deposition layer (step 310). FIG. 4B is a schematic cross-sectional view of the patterned high etch rate photoresist mask 412 with a protective layer 420 deposited over the sidewalls of the high etch rate photoresist mask mask. The protective layer 420 forms a sidewall layer feature 424 within the mask spaces, where the sidewall layer feature 424 has a reduced space CD that is less than the space CD of the high etch rate photoresist mask. Preferably, the reduced space CD of the deposited high etch rate photoresist mask is 50% less than the space CD of the high etch rate photoresist mask feature. It is also desirable that the sidewall layer has substantially vertical sidewalls 428, which are highly conformal as shown. An example of a substantially vertical sidewall is a sidewall that from bottom to top makes an angle of between 88° to 90° with the bottom of the feature. Conformal sidewalls have a deposition layer that has substantially the same thickness from the top to the bottom of the feature. Non-conformal sidewalls may form a faceting or a bread-loafing formation, which provide non-substantially vertical sidewalls. Tapered sidewalls (from the faceting formation) or bread-loafing sidewalls may increase the deposited layer CD and provide a poor etching mask. Preferably, the deposition on the side wall is thicker than the deposition on the bottom of the first mask feature. More preferably, no layer is deposited over the bottom of the first mask feature. In this example, the protective layer is not deposited on the top horizontal surface of the high etch rate photoresist mask.

The high etch rate photoresist mask is removed (step 311). Because the high etch rate photoresist mask is preferably free of etch resistance additive, the high etch rate photoresist may be removed without significantly removing the protective layer. FIG. 4C is a cross sectional view of the stack after the high etch rate photoresist mask is removed.

Features are then etched into the etch layer to 408 (step 312). FIG. 4D shows a feature 432 etched into the layer to be etched 408. The protective layer may then be removed (step 316). In this example, the protective layer and ARL may be removed in a single stripping step. FIG. 4E shows the stack after the deposition layer and etch mask have been removed. The line width of the etch layer is shown as L_{f}. The space width of the features in the etch layer is shown as S_{f}. The pitch length of the features is shown as P_{f}, where P_{f}=L_{f}+S_{f}. For comparison, photoresist mask pitch Pₚ, photoresist line width Lₚ, and photoresist spacing Sₚ from FIG. 4A, are shown in FIG. 4E for comparison with feature pitch P_{f}, feature line width L_{f}, and feature space width S_{f}. In this embodiment, the length of the pitch for the features P_{f} is half the length of the pitch of the photoresist mask Pₚ, since the line width between features L_{f} is half of the line width of the photoresist mask Lₚ and the feature space width S_{f} is half of the space in the photoresist mask Sₚ. Therefore, the inventive process is able to double etch feature resolution, by reducing pitch length, line width, and feature width by half, while using the same photoresist lithography process. Additional formation steps may be performed (step 320). For example, the additional steps may be used to form memory devices.

Preferably, the sidewalls have a width that is 30% to 70% the width Lₚ of the lines. More preferably, the sidewalls have a width that is 40% to 60% the width Lₚ of the lines.

In other embodiments, where a metal or a silicon layer is to be etched, the protective layer may be of a more etch resistant layer, such as a silicon nitride material.

In other embodiments of the invention, the temperature of the wafer is kept below glass transition temperature of the photoresist materials to avoid distortion of the photoresist mask features. Preferably, the wafer temperature is kept in the range from 100 C to −100 C. More preferably, the temperature is kept in the range of 80 C to −80 C. Most preferably, the temperature is maintained in the range of 40 C to −40 C.

One advantage of the inventive process is that a non-vertical deposition profile can be made more vertical by the subsequent profile shaping step. Another advantage of the inventive process is that deposition layers may be added and etch back resulting in a thin deposition layer formed during each cycle. Such a thin later can help to prevent delamination, which can be caused by forming a single thick layer. A single thick film may also cause other problems. In addition the cyclical process provides more control parameters, which allow for more tuning parameters, to provide a better conformal deposition layer. Since the cyclic process will keep the bread-loaf at a minimum throughout the CD reduction process, the CD gains at the bottom portion of the deposition profile can keep growing.

In one embodiment of the invention, the protective layer is of a carbon and hydrogen material.

This embodiment allows the reduction of pitch length of the etched features with respect to the pitch length limitation by the resolution of the lithography system.

Since etch resistance additives may be transparent to one exposure frequency but not another, an etch resistance additive may be useful in one lithographic process using one frequency but not in another lithographic process using another frequency. Since the invention uses a photoresist free of the etch resistance additive, an advantage of the invention is that a single polymer may be used for various lithographic exposure frequencies.

While this invention has been described in terms of several preferred embodiments, there are alterations, permutations, and various substitute equivalents, which fall within the scope of this invention. It should also be noted that there are many alternative ways of implementing the methods and apparatuses of the present invention. It is therefore intended that the following appended claims be interpreted as including all such alterations, permutations, and various substitute equivalents as fall within the true spirit and scope of the present invention.

What is claimed is:

1. A method for etching features into an etch layer, comprising:
forming a patterned mask over the etch layer, wherein the patterned mask is of a high etch rate photoresist material, wherein the patterned mask has patterned mask features;
depositing a protective layer on the patterned mask of high etch rate photoresist material by performing a cyclical deposition, wherein each cycle, comprises:
a depositing phase for depositing a deposition layer over the exposed surfaces, including sidewalls of the patterned mask of high etch rate photoresist material; and
a profile shaping phase for providing vertical sidewalls;
etching features into the etch layer using the protective layer as a mask; and
removing the protective layer.

2. The method, as recited in claim 1, wherein the high etch rate photoresist is an etch resistance additive free.

3. The method, as recited in claim 2, wherein the cyclical deposition of the protective layer is performed for two to three cycles.

4. The method, as recited in claim 3, wherein the protective layer and patterned mask is used as a mask for etching the features into the etch layer.

5. The method, as recited in claim 4, wherein the removing the protective layer, also strips the patterned mask of high etch rate photoresist material.

6. The method, as recited in claim 5, wherein the protective layer has sidewalls with a thickness between 0.5 nm to 10 nm thick.

7. The method, as recited in claim 2, wherein the high etch rate photoresist material is free from chemical amplifier additives.

8. The method, as recited in claim 2, wherein the depositing the protective layer does not form a protective layer across bottoms of the patterned mask features.

9. The method, as recited in claim 2, further comprising:
removing the patterned mask of high etch rate photoresist material without removing sidewalls formed by the protective layer, before etching the features into the etch layer, wherein the etching features into the etch layer uses the sidewalls of the protective layer as a mask.

10. The method, as recited in claim 2, wherein the patterned mask has a patterned mask pitch length and wherein the etch features have a pitch length that is less than the patterned mask pitch length.

11. The method, as recited in claim 2, wherein the depositing the protective layer does not form a protective layer on horizontal surfaces.

12. The method, as recited in claim 2, wherein the depositing phase comprises:
flowing a depositing gas;
forming the depositing gas into a plasma; and
stopping the flow of the depositing gas.

13. The method, as recited in any of claims 1, wherein the profile shaping phase, comprises:
flowing a profile shaping gas;
forming the profile shaping gas into a plasma; and
stopping the flow of the profile shaping gas.

14. An apparatus for forming features in an etch layer, wherein the layer is supported by a substrate and wherein the etch layer is covered by a patterned high etch rate photoresist mask with mask features, wherein the high etch rate photoresist is free of etch resistance additives, comprising:
a plasma processing chamber, comprising:
a chamber wall forming a plasma processing chamber enclosure;
a substrate support for supporting a substrate within the plasma processing chamber enclosure;
a pressure regulator for regulating the pressure in the plasma processing chamber enclosure;
at least one electrode for providing power to the plasma processing chamber enclosure for sustaining a plasma;
a gas inlet for providing gas into the plasma processing chamber enclosure; and
a gas outlet for exhausting gas from the plasma processing chamber enclosure;
a gas source in fluid connection with the gas inlet, comprising;
a deposition gas source;
a profile shaping gas source; and
an etch gas source
a controller controllably connected to the gas source and the at least one electrode, comprising:
at least one processor; and
computer readable media, comprising:
computer readable code for providing for two to three cycles a protective layer deposition that forms a protective layer with sidewalls with a thickness between 0.5 nm and 30 nm wherein each cycle, comprising:
computer readable code for providing a flow of a deposition gas from the deposition gas source to the plasma processing chamber enclosure;
computer readable code for forming the deposition gas into a plasma;
computer readable code for stopping the flow of the deposition gas to the plasma processing chamber enclosure;
computer readable code for providing a flow of a profile shaping gas from the profile shaping gas source to the plasma processing chamber enclosure after the flow of the first deposition gas is stopped;
computer readable code for forming the profile shaping gas into a plasma; and
computer readable code for stopping the flow of the profile shaping gas to the plasma processing chamber enclosure;
computer readable code for providing a flow of an etchant gas from the etchant gas source to the plasma processing chamber;
computer readable code for etching features in the etch layer, using the etchant gas; and
computer readable code for stripping the protective layer and the high etch rate photoresist mask.

15. A method for etching features into an etch layer, comprising:
forming a patterned mask over the etch layer, wherein the patterned mask is of a high etch rate photoresist material, wherein the patterned mask has patterned mask features;
depositing a protective layer on the patterned mask of high etch rate photoresist material by performing a cyclical deposition, wherein each cycle, comprises:
a depositing phase for depositing a deposition layer over the exposed surfaces, including sidewalls of the patterned mask of high etch rate photoresist material; and
a profile shaping phase for providing vertical sidewalls;
removing the high etch rate photoresist material, and leaving sidewalls of the protective layer;
etching features into the etch layer using the sidewalls of the protective layer as a mask; and
removing the protective layer.

16. The method, as recited in claim 15, wherein the high etch rate photoresist is an etch resistance additive free.

17. The method, as recited in claim 16, wherein the depositing the protective layer does not form a protective layer on top of the high etch rate photoresist mask.

18. An apparatus for forming features in an etch layer, wherein the layer is supported by a substrate and wherein the etch layer is covered by a patterned high etch rate photoresist mask with mask features, wherein the high etch rate photoresist is free of etch resistance additives, comprising:
a plasma processing chamber, comprising:
a chamber wall forming a plasma processing chamber enclosure;
a substrate support for supporting a substrate within the plasma processing chamber enclosure;
a pressure regulator for regulating the pressure in the plasma processing chamber enclosure;
at least one electrode for providing power to the plasma processing chamber enclosure for sustaining a plasma;
a gas inlet for providing gas into the plasma processing chamber enclosure; and
a gas outlet for exhausting gas from the plasma processing chamber enclosure;
a gas source in fluid connection with the gas inlet, comprising;
a deposition gas source;
a profile shaping gas source; and
an etch gas source
a controller controllably connected to the gas source and the at least one electrode, comprising:
at least one processor; and
computer readable media, comprising:
computer readable code for providing a plurality of cycles for forming a protective layer with sidewalls, where the protective layer is not formed on top surfaces of the high etch rate photoresist wherein each cycle, comprising:
computer readable code for providing a flow of a deposition gas from the deposition gas source to the plasma processing chamber enclosure;
computer readable code for forming the deposition gas into a plasma;
computer readable code for stopping the flow of the deposition gas to the plasma processing chamber enclosure;
computer readable code for providing a flow of a profile shaping gas from the profile shaping gas source to the plasma processing chamber enclosure after the flow of the first deposition gas is stopped;
computer readable code for forming the profile shaping gas into a plasma; and
computer readable code for stopping the flow of the profile shaping gas to the plasma processing chamber enclosure;
computer readable code for removing the high etch rate photoresist without removing the sidewalls of the protective layer;
computer readable code for providing a flow of an etchant gas from the etchant gas source to the plasma processing chamber;
computer readable code for etching features in the etch layer, using the etchant gas and using the protective layer sidewalls as a mask; and
computer readable code for stripping the protective layer and the high etch rate photoresist mask.

19. A method for etching features into an etch layer, comprising:
forming a patterned mask over the etch layer, wherein the patterned mask is of a high etch rate photoresist material, wherein the patterned mask has patterned mask features;
depositing a protective layer on the patterned mask of high etch rate photoresist material by performing a cyclical deposition, wherein each cycle, comprises:
a depositing phase for depositing a deposition layer over the exposed surfaces, including sidewalls of the patterned mask of high etch rate photoresist material; and
a profile shaping phase for providing vertical sidewalls, wherein the protective layer is deposited over the top and sidewalls of the high etch rate photoresist mask;
etching features into the etch layer using the protective layer as a mask; and
removing the protective layer.

20. The method, as recited in any of claims 19, wherein the depositing the protective layer does not form a protective layer on horizontal surfaces at bottoms of the mask features.
